(19) United States
(12) Patent Application Publication
(10) Pub. No.: US 2026/0001154 A1
(43) Pub. Date: Jan. 1, 2026

(54) WAVE HEIGHT CONTROL FOR WAVE SOLDERING

(71) Applicant: Schweitzer Engineering Laboratories, Inc., Pullman, WA (US)

(72) Inventor: Frederick W. Pollard, Potlatch, ID (US)

(73) Assignee: Schweitzer Engineering Laboratories, Inc., Pullman, WA (US)

(21) Appl. No.: 18/756,631

(22) Filed: Jun. 27, 2024

(51) Int. Cl. B23K 3/08; B23K 3/06; B23K 101/42; G01B 7/02; H05K 13/04; H05K 13/08

(52) U.S. Cl. CPC B23K 3/08; B23K 3/0653; G01B 7/023; B23K 2101/42; H05K 13/0465; H05K 13/082; H05K 13/083

(57) ABSTRACT

A soldering system includes a first solder wave height sensor to generate a first sensor signal and a second solder wave height sensor to generate a second sensor signal. The system further includes control circuitry to control an operation of the soldering system based on the first sensor signal and the second sensor signal.

### BACKGROUND

This disclosure relates to systems and methods for sensing and controlling wave height for a wave soldering system.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of any kind.

Wave soldering is a widely used operation for Printed Circuit Board (PCB) production, used to simultaneously solder multiple surface components of a single PCB. Specifically, one or more PCBs are passed over a soldering wave having molten metal, such as a solder alloy, where the wave may precisely coat the surface components of the PCB. As such, the wave height and wave height variability may be controlled or adjusted to maintain a desired configuration to effectively solder the components of PCB. Current control systems may utilize one or more sensors to detect a height of the solder wave in one or more locations. Based on the detected wave height, PCB production may be halted, and the solder wave height may be adjusted by one or more methods. Further, current control systems may utilize human inspection to monitor the quality of the wave soldering to detect defects. However, current wave height detection and control methods may result in undesirable, inefficient operation of the wave soldering process.

### BRIEF DESCRIPTION OF THE DRAWINGS

FIG. 1 is a schematic diagram of an embodiment of a wave soldering system, in accordance with embodiments described herein;

FIG. 2 is a perspective view of a PCB positioned over a soldering wave of an embodiment of the wave soldering system, in accordance with embodiments described herein;

FIG. 3 is a schematic diagram of an embodiment of two soldering wave height sensors, in accordance with embodiments described herein;

FIG. 4 is a block diagram of a control system for soldering wave height of an embodiment of the wave soldering system, in accordance with embodiments described herein;

FIG. 5 is a block diagram of a control system for wave producing machine height of an embodiment of the wave soldering system, in accordance with embodiments described herein; and

FIG. 6 is a schematic diagram of multiple wave configurations for an embodiment of the wave soldering system, in accordance with embodiments described herein.

### DETAILED DESCRIPTION

One or more specific embodiments of the present disclosure will be described below. These described embodiments are examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions may be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/−5%, within +/−4%, within +/−3%, within +/−2%, within +/−1%, or even closer, of the given value. Similarly, when a given feature is described as being “substantially parallel” to another feature, “generally perpendicular” to another feature, and so forth, this is intended to convey that the given feature is within +/−5%, within +/−4%, within +/−3%, within +/−2%, within +/−1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

Printed Circuit Boards (PCBs) are common electrical components used in almost any electrical system in modern day technology. Specifically, PCBs provide electrical and structural support for one or more components housed on a substrate of the PCB. The one or more components housed on the PCB require strong reliable connections between other components of the PCB and other components of an electrical system interacting with the PCB. As such, PCB components are soldered (e.g., welded) using molten metal (e.g., molten metal alloys, conductive metals) to electrically couple and secure the one or more components. Further, soldering PCB components may reduce overheating of the PCB components, create mechanical stability of the PCB components, and/or increase PCB resistance to corrosive elements (e.g., water).

In some embodiments, soldering PCB components may include soldering each individual component at separate times (e.g., sequential soldering). However, this process is time extensive, and may be impractical for mass production of PCB boards. As such, wave soldering systems may be used to solder multiple PCB components simultaneously, and multiple PCB boards in an assembly like manner. Specifically, multiple PCB boards, each including multiple PCB components, may be passed over a soldering wave (e.g., molten metal wave, molten soldering metal wave, molten alloy wave) to solder the multiple PCB components during a single pass. The soldering wave may be monitored by one or more sensors to detect a height of the soldering wave, where the detection of the soldering wave height may be used to adjust the soldering wave to a desired height. However, existing detection and control methods may be susceptible to the heat of the soldering wave and/or may not efficiently monitor and adjust the soldering wave height and/or height variability across a dimension of the soldering wave.

As such, present embodiments are related to improved monitoring and control methods for the soldering wave in a wave soldering system for PCBs. For example, an embodiment of the wave soldering system may include one or more soldering wave height sensors to detect the height of the soldering wave, where the detected height may be used (e.g., compared to a set point height, threshold height) to adjust the soldering wave to a desired height (e.g., the set point height). Further, the one or more soldering wave height sensors may include thermal protection (e.g., a thermal resistant layer), such as nano-particle coating, thermal cap, thermal regulators, to reduce mechanical complications associated with high thermal energy dissipating from the soldering wave. As such, present embodiments may decrease failure rates of the soldering wave height sensors, reducing maintenance down time and thereby increasing PCB production. Further, present embodiments are related to a control system including two or more soldering wave height sensors positioned at different locations across one or more dimensions (e.g., width, length) of the soldering wave. For example, soldering wave height sensors positioned at various locations across the soldering wave may detect the soldering wave height, where the soldering wave heights across the dimensions of the soldering wave may be used to determine height variability across the soldering wave. Soldering wave height variability may be used to control one or more aspects of the wave soldering system, such as, adjusting the height of the soldering wave, the height of the soldering wave producing machine (e.g., solder pot) or stopping (e.g., suspending) the assembly process. In any case, control based on soldering wave height and/or soldering wave height variability may increase the quality of the PCB soldering as well as increasing efficiency in production of the PCBs.

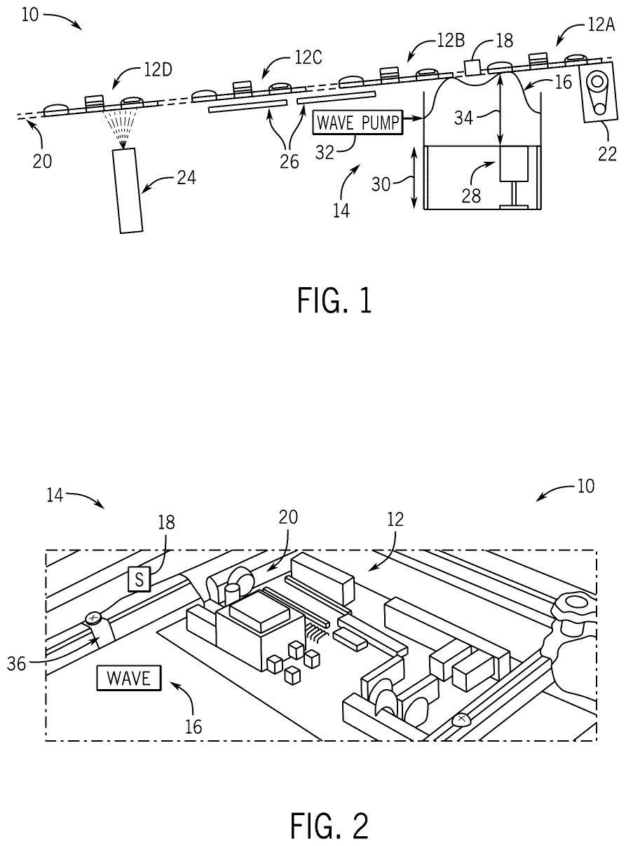

Referring now to the figures, FIG. 1 illustrates a schematic side view of a wave soldering system 10 to solder PCB components simultaneously. The wave soldering system 10 may include a production track 20 (e.g., conveyer belt, assembly line) advanced by one or more actuators 22 (e.g., electric motor) to transfer PCBs 12 (e.g., substrates, motherboards) across one or more assembly components in a batch processing operation. For example, PCBs 12 may be coupled to the production track 20 via hooks disposed on a side of the wave soldering system 10, such that a bottom of the PCBs 12 are exposed for processing by the one or more assembly components. In some embodiments, the wave soldering system 10 may include a cleaning component 24, such as a fluxer, to clean and prepare the PCB 12 for further processing. For example, PCB 12D may be transferred across the operating area of the cleaning component 24 to clean a bottom of the PCB 12D, which may include the one or more PCB 12D components. Further, the wave soldering system 10 may include one or more heaters 26 to preheat the one or more PCB components prior to a wave soldering process. For example, one or more heaters 26 may be positioned under a PCB 12C, 12B to preheat the PCB 12C, 12B components. By preheating the PCB 12 components, excess moisture may be removed from the PCB 12, enabling increased adhesion of soldering metal during a wave soldering process. Further, preheating the PCB 12 components may result in uniform temperature increases which may reduce defects to the PCB 12 components.

In any case, the PCBs 12 may transfer over a soldering wave 16 of the soldering wave producing machine 14 (e.g., solder pot), where the soldering wave 16 may apply soldering material (e.g., lead alloys, tin alloys, silver alloys, copper alloys, and/or any other suitable metal) to the one or more PCB components, disposed at the bottom of the PCB 12. For example, PCB 12A, 12B may pass over the soldering wave 16 such that the bottom of the PCB 12A, 12B is contacted with the soldering wave 16. As such, molten soldering material of the soldering wave 16 may be deposited onto the one or more PCB 12 components disposed on the bottom of the PCB 12A, 12B. Advantageously, PCBs 12 may be passed continuously over the soldering wave 16 of the wave soldering system 10 to solder multiple PCBs 12 in an assembly-line like process.

As will be appreciated, in order to sufficiently solder the PCB 12 components, the contact depth (e.g., depth of the PCB 12 in the molten material) between the PCB 12 and the soldering wave 16 may be minimal (e.g., 1 mm, 2 mm, 3 mm etc.). As such, one or more detection and control methods may be utilized to maintain a desirable height of the soldering wave 16, and a desirable contact depth between the PCB 12 and the soldering wave 16. For example, one or more sensors 18 (e.g., soldering wave height sensors, eddy current sensors) may be positioned adjacent (e.g., over) the soldering wave 16 to detect a height 34 (e.g., a position of the peak of the wave relative to the PCBs 12) of the soldering wave 16. Upon determining the height 34 of the soldering wave 16 and the relative position of the PCB 12 on the production track 20, control circuitry and/or an operator may determine the depth of the PCB 12 in the soldering wave 16. Therefore, the sensor 18 and control circuitry may detect and adjust the height 34 of the soldering wave 16 to achieve a desired depth of the PCB 12 in the soldering wave 16.

Upon detection of the height 34 of the soldering wave 16, the control circuitry may adjust the height 34 via a wave pump 32 and/or an actuator 28 for the soldering wave producing machine 14. Specifically, a wave pump 32 speed or power may be adjusted to increase or decrease a height of the soldering wave 16 based on a detected height 34 (e.g., detected height by sensor 18) and/or a desired depth of the PCB 12 in the soldering wave 16. Alternatively, or simultaneously, the actuator 28 may be controlled to adjust (e.g., increase, decrease) a height 30 of the soldering wave producing machine 14 based on the detected height and/or the desired depth of the PCB 12 in the soldering wave 16.

FIG. 2 illustrates a perspective view of an embodiment of the wave soldering system 10. As illustrated, the PCB 12 may be passed over the soldering wave 16 such that one or more components disposed on the bottom of the PCB 12 may be soldered. As discussed above, the PCB 12 may be coupled to the production track 20 via one or more hooks 36 disposed on sides of the production track 20. In this way, the bottom of the PCB 12 may be exposed to one or more processing components of the wave soldering system 10. The production track 20 and or hooks 36 may be adjusted to achieve a desired depth of the PCB 12 in the soldering wave 16. For example, a position of the production track 20 and/or hooks 36 may be adjusted based on the desired depth of the PCB 12 in the soldering wave 16, a physical parameter of the PCB 12, a physical parameter of the one or more PCB 12 components disposed on the bottom of the PCB 12, and/or a height of the soldering wave 16.

One or more sensors 18 may be positioned proximate the soldering wave 16 to measure or detect one or more parameters of the soldering wave 16. In an exemplary embodiment, a sensor of the one or more sensors 18 may include an eddy current sensor to detect a height of the soldering wave 16. Specifically, the sensor 18 may be positioned over the soldering wave 16, such that a sensing portion (e.g., sensing coils) of the sensor 18 is proximate the soldering wave 16. The sensor 18 may be positioned on an outside of the PCB 12 path of the production track 20, such that the movement of the PCB 12 over the soldering wave 16 does not interfere with the detection of the soldering wave height by the sensor 18. Although one sensor 18 is illustrated in the figure, it should be appreciated that any number (e.g., 2, 3, 4, 5) of sensors 18 may be utilized in the wave soldering system 10. For example, a second sensor 18 may be disposed on the opposite side of the illustrated production track 20, to also detect the height of the soldering wave 16. In this way, the sensors 18 may detect soldering wave height variability across one or more dimensions (e.g., width, length) of the soldering wave 16. In some embodiments, the sensor 18 may be disposed on the production track 20 (e.g., below the production track 20).

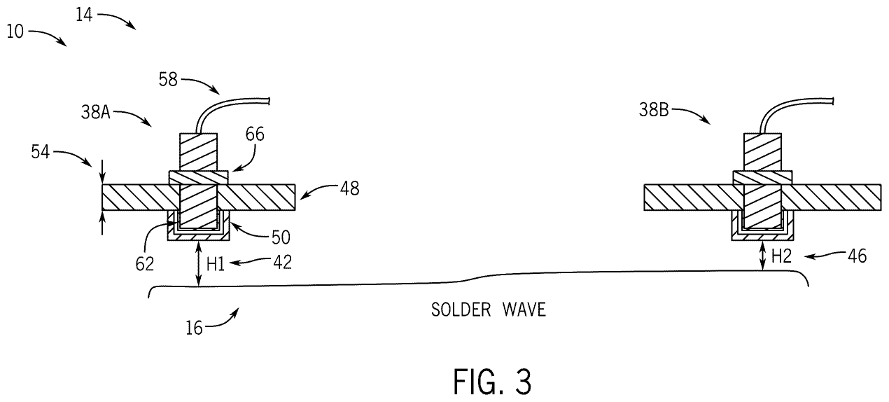

Referring now to FIG. 3, an embodiment of two soldering wave height sensors 38 are illustrated. In some embodiments, the soldering wave height sensor 38 may be used in the wave soldering system 10 discussed above as the sensor 18 or in conjunction with the sensor 18. As will be appreciated, soldering wave height sensors 38 may be sensors (e.g., eddy current sensors) that utilize eddy currents to sense or detect a displacement between the soldering wave height sensors 38 and a material (e.g., metallic material, conducting material). For example, the soldering wave height sensors 38 may include one or more sensing coils disposed internal to the soldering wave height sensors 38 to create a magnetic field via, such as, circulating electricity through the sensing coils. Advantageously, the soldering wave height sensors 38 may be non-contact sensors, and may detect the height of the soldering wave 16 without contacting the molten material of the soldering wave 16. Upon positioning the soldering wave height sensor 38 proximate the molten material, the magnetic field created by the sensing coils may interact with the molten material. For example, the magnetic field may induce eddy currents within the molten material that may vary (e.g., vary in strength) passed on a distance from the soldering wave height sensors 38. As the molten material becomes nearer or further to the soldering wave height sensors 38, the eddy currents within the molten material are altered (e.g., increased, decreased). The alteration of the eddy currents may be detected by the soldering wave height sensors 38 and may be converted (e.g., converted to distance) by the soldering wave height sensors 38 and/or control circuitry. As such, the soldering wave height sensors 38 may detect the height of the soldering wave 16 by detecting varying parameters of the eddy currents induced by the sensing coils, without contacting the molten material.

As discussed above, the wave soldering system 10 may include any number of soldering wave height sensors 38 to detect or measure one or more parameters of the soldering wave 16. For example, in some embodiments, the soldering wave height sensor 38 (e.g., 38A, 38B) may detect a height 42, 46 (e.g., soldering wave height) of the soldering wave 16. In some embodiments, the wave soldering system 10 may include two or more soldering wave height sensor 38 (e.g., 38A, 38B) positioned at varying locations of the soldering wave 16. For example, the soldering wave height sensor 38A may be positioned at a first side of the soldering wave 16 and another soldering wave height sensor 38B may be positioned at a second side of the soldering wave 16. In this way, height variability (e.g., soldering wave height variability) of the soldering wave 16 (e.g., the difference between height 42 and height 46, or vice versa) may be detected. For example, soldering wave height sensor 38A may detect and/or measure height 42 proximate the first side of the soldering wave 16. Likewise, soldering wave height sensor 38B may detect and/or measure height 46 proximate the second side of the soldering wave 16. The difference, if any, of the height 42 and the height 46 may be determined (e.g., determined via control circuitry) to determine height variability across a dimension (e.g., length, width) of the soldering wave 16. Based on the height variability, one or more actions may be performed by the wave soldering system 10, such as, adjusting the height of the soldering wave 16, adjusting a baffle of the soldering wave producing machine 14 (e.g., solder pot), stopping (e.g., suspending) the movement of the PCB over the soldering wave 16, and/or adjusting one or more parameters of the soldering wave producing machine 14. In this way, the wave soldering system 10 may experience increased uniformity in soldering of the PCB with reduced downtime due to maintenance.

Although two soldering wave height sensors 38 are illustrated, it will be appreciated that any number (e.g., 2, 3, 4, 5, 6, 7) of soldering wave height sensors 38 may be utilized in the wave soldering system 10 to control one or more aspects of the soldering wave producing machine 14 and/or another component of the wave soldering system 10. For example, additional (e.g., more than two) soldering wave height sensors 38 may be utilized. In this way, height variability may be determined with increased precision, compared to systems with a lessor amount of soldering wave height sensors 38. As such, control circuitry may control one or more aspects of the soldering wave producing machine 14 to adjust (e.g., precisely adjust, finely adjust) the height variability of the soldering wave 16, thereby increasing uniformity of the soldering of the PCB passing over the soldering wave 16.

In some embodiments, multiple soldering wave height sensors 38 may be positioned on the first side (e.g., outside of a first production track) of the soldering wave 16. Similarly, multiple soldering wave height sensors 38 may be positioned on the second side (e.g., outside of the second production track) of the soldering wave 16. In this way, the soldering wave height sensors 38 may detect height variability of the soldering wave 16 over multiple dimensions (e.g., length, width, diagonally) of the soldering wave 16. For example, the soldering wave height sensors 38 may detect height variability over a first dimension extending with (e.g., substantially parallel) the flow of the molten material. Further, soldering wave height sensors 38 may detect height variability over a second dimension extending cross-wise (e.g., substantially perpendicular) to the flow of molten material of the soldering wave 16. In some embodiments, two or more soldering wave height sensors 38 may detect height at diagonal positions of the soldering wave 16. In this way, control circuitry may determine height variability across multiple dimensions of the soldering wave 16, and may further adjust the soldering wave 16 accordingly (e.g., based on the height variability across all portions of the soldering wave 16).

In some embodiments, the soldering wave height sensors 38 may be coupled to the wave soldering system 10 by a support structure 48 (e.g., mount). For example, the support structure 48 may couple to a side or the wave soldering system 10 (e.g., an outer boundary), a production track, or both. The soldering wave height sensor 38 may be coupled to the support structure 48 by any suitable method. For example, the support structure 48 may include a hole to receive the soldering wave height sensor 38 such that at least a portion (e.g., sensing side) of the soldering wave height sensor 38 is disposed on one side (e.g., a soldering wave side) of the support structure 48, and at least a portion of the soldering wave height sensor 38 is disposed on an opposite side (e.g., a non-soldering wave side) of the support structure 48. In this way, only the sensing side of the soldering wave height sensor 38 may be exposed to the thermal energy of molten material of the soldering wave 16. As such, the soldering wave height sensor 38 may experience reduced thermal energy retention, thereby reducing damage associated with high thermal energy.

The support structure 48 may include any suitable dimensions (e.g., length, width, thickness) to reduce thermal energy retained by the soldering wave height sensor 38 while supporting the soldering wave height sensor 38 in a desired sensing position. For example, the support structure 48 may have a thickness 54 suitable to reduce thermal energy from dissipating from the molten material of the soldering wave 16 to components of the soldering wave height sensor 38, such as sensing coils, communication components 58. In some embodiments, the support structure 48 may move (e.g., move with the soldering wave height sensor 38) relative to the wave soldering system 10. In this way, the soldering wave height sensor 38 may be disposed at various locations of the soldering wave 16, depending on a desired wave configuration and/or a desired sensing location. Additionally, the support structure 48 may include any material suitable to withstand high thermal energy dissipation from the soldering wave 16, to shield the soldering wave height sensor 38 from high thermal energy dissipation of the soldering wave 16, and/or to support the suspension of the soldering wave height sensor 38 over the soldering wave 16. For example, the support structure 48 may include aluminum, heat resistant metal, heat resistant alloys, or any other suitable materials capable of providing heat resistance and structural support to the soldering wave height sensors 38.

In some embodiments, the soldering wave height sensor 38 may include a heat resistant layer 50 (e.g., thermal resistant layer) to shield the soldering wave height sensor 38 from the thermal radiation dissipating from the molten material of the soldering wave 16. For example, the soldering wave height sensor 38 may include the heat resistant layer 50 disposed on the sensing side, proximate the soldering wave 16. The heat resistant layer 50 may encapsulate (e.g., surround) the sensing side of the soldering wave height sensor 38 to reduce exposure of the soldering wave height sensor 38 to the thermal energy dissipation of the soldering wave 16. In some embodiments, the heat resistant layer 50 may extend from the distal end of the sensing side of the soldering wave height sensor 38 to the support structure 48, encapsulating the side (e.g., sensing side) of the soldering wave height sensor 38 extending through the support structure 48.

In an embodiment, the heat resistant layer 50 may include a nano-material coating (e.g., thermal resistant layer) to shield the soldering wave height sensor 38 from thermal energy dissipation of the soldering wave 16. For example, the heat resistant layer 50 may include nanobead ceramic or glass beads, also called hollow silica nanospheres. In the context of this disclosure, “nano” refers to material with a particle dimension between the range of 1 to 100 nanometers. As will be appreciated, the use of heat resistant layer 50 may reduce the thermal conductivity of the soldering wave height sensor 38, reducing thermal energy transfer between the molten material of the soldering wave 16 and the soldering wave height sensor 38. In this way, the soldering wave height sensors 38 may experience reduced sensor distortion and/or degradation due to high thermal energy dissipation from the soldering wave 16. Furthermore, heat resistant layer 50 may also reduce and/or prevent molten material from depositing on the soldering wave height sensor 38 (e.g., sensing side of soldering wave height sensor 38). In some embodiments, the wave soldering system 10 may include additional molten material deposit reducing methods in addition to the heat resistant layer 50. For example, the wave soldering system 10 may include an air directing device that may direct air over the soldering wave height sensors 38. The directed air may force the deposited molten material off of the wave height sensors 38 either automatically or based on a detected parameter. In this way, the sensing capabilities of the soldering wave height sensors 38 may not be reduced by deposited molten material. Further, as will be appreciated, reduction and/or prevention of molten material depositing on the soldering wave height sensors 38 may also reduce false alarms (e.g., alarms alerting of soldering wave height sensor 38 complications).

In some embodiments, the heat resistant layer 50 may be any suitable thickness as to reduce thermal energy transfer between the soldering wave 16 and the soldering wave height sensor 38, while also maintaining the sensing capabilities of the soldering wave height sensor 38. The heat resistant layer 50 may be applied to the soldering wave height sensor 38 by any suitable method, such as, spray coating (e.g., air spray coating, airless spray coating, electrostatic spray coating), dipping, brushing, spin coating, or any other suitable method. In some embodiments, multiple layers of the heat resistant layer 50 may be applied to the soldering wave height sensor 38. For example, a first layer may include a first type of material (e.g., nanobead) while a second layer may include a second type of material (e.g., nanobead).

In some embodiments, the soldering wave height sensor 38 may include a cap 62, in addition or as an alternate to the heat resistant layer 50. For example, the cap 62 may include a heat resistant material, such as aluminum or an alloy, that may provide heat resistance to the components (e.g., sensing coils, communication components 58) of the soldering wave height sensor 38. In some embodiments, the cap 62 may encapsulate (e.g., surround) the sensing side of the soldering wave height sensor 38 to reduce exposure of the soldering wave height sensor 38 to the thermal energy dissipation of the soldering wave 16. In the illustrated embodiment, the cap 62 extends from the distal end of the sensing side of the soldering wave height sensor 38 to the support structure 48, encapsulating the entire side (e.g., sensing side) of the soldering wave height sensor 38 extending through the support structure 48. However, in some embodiments, the cap 62 may encapsulate other portions of the soldering wave height sensor 38, such as, the portion of the soldering wave height sensor 38 disposed on the non-wave side of the support structure 48. The cap 62 may be coupled to the soldering wave height sensor 38 by any suitable means, such as, mechanical fasteners, friction fit, chemical adhesives, and/or any other suitable methods. Further, as discussed above, the heat resistant layer 50 may be applied over and/or under the cap 62 to further increase thermal energy resistance of the soldering wave height sensors 38.

In some embodiments, the cap 62 and the heat resistant layer 50 may be coupled to the support structure 48 and may receive the soldering wave height sensor 38. For example, the cap 62 may be coupled directly to a bottom side of the support structure 48, where the cap 62 and the support structure 48 define a cavity that may receive the soldering wave height sensor 38. Further, the heat resistant layer 50 may be coupled (e.g., applied) to the cap 62 and/or the support structure 48. In this way, the soldering wave height sensor 38 may be removably coupled to an assembly of a combination of the support structure 48, the cap 62 and/or the heat resistant layer 50. As such, the soldering wave height sensor 38 may be readily removed for maintenance, upgrading, and/or replacement without requiring a new application of the cap 62 and/or the heat resistant layer 50.

In an embodiment, the soldering wave height sensor 38 may include one or more thermal regulators 66 to thermally regulate (e.g., heat, cool) the soldering wave height sensors 38. For example, the thermal regulator 66 may encircle at least a portion of the soldering wave height sensor 38, and may cool or heat the soldering wave height sensor 38 to maintain a desired internal and/or external temperature of the soldering wave height sensor 38. In this way, the soldering wave height sensor 38 may experience increased (e.g., more accurate, more precise) sensing capabilities. As illustrated, the thermal regulator 66 may be disposed on a side of the support structure 48 opposite of the soldering wave 16. However, it will be appreciated the thermal regulator 66 may be disposed on the soldering wave 16 side (e.g., sensing side) of the support structure 48, such as under the cap 62 and/or over the cap 62 and under the heat resistant layer 50. Although one thermal regulator 66 is shown, it will be appreciated that any number of thermal regulators 66 may be disposed on the soldering wave height sensor 38, such as, above and/or below the illustrated thermal regulator 66.

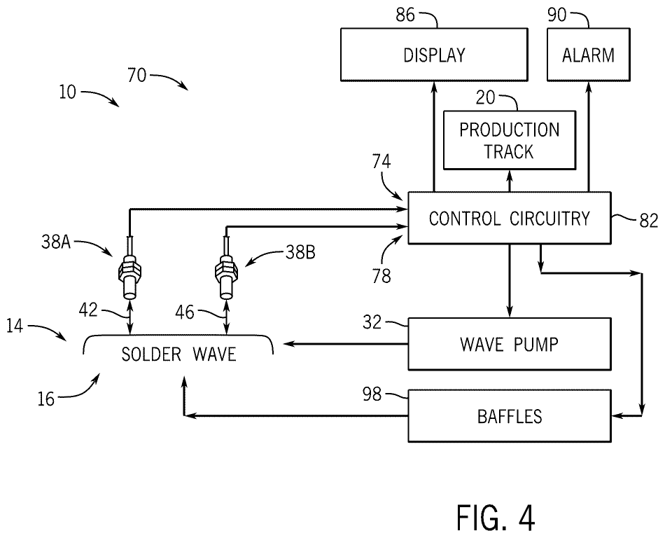

Referring now to FIG. 4, a block diagram of a control system 70 for a wave soldering system 10 is shown. As discussed above, one or more soldering wave height sensors 38 may be disposed adjacent to the soldering wave 16 to detect and/or measure a parameter of the soldering wave 16, such as a height 42, 46 (e.g., wave height). Each soldering wave height sensor 38A, 38B may detect and send measurements indicating a wave height (e.g., height 42, 46) to one or more input pins 74, 78 of control circuitry 82. For example, the soldering wave height sensors 38A, 38B may each receive data indicative of a wave height (e.g., changes of electrical properties of the soldering wave 16 (e.g., Eddy currents) and/or changes in the magnetic field of the sensing coils) and send said data, via an electrical signal, to the control circuitry 82. The control circuitry 82 may then convert the electrical signal, including data indicative of the height 42, 46, to a measure of distance (e.g., a height measured in a distance (e.g., millimeters, centimeters)). In some embodiments, the soldering wave height sensors 38 may include internal control circuitry to convert the detected data into a converted wave height, wherein the converted wave height, may further be relayed to the control circuitry 82 to make one or more determinations and/or perform one or more actions.

In an embodiment, the control circuitry 82 may output an electrical signal to a display 86 (e.g., digital screen, GUI, electronic display) to display a real-time solder height to an operator of the wave soldering system 10. For example, upon determination of the height 42 or wave height 46, the control circuitry 82 may send an electrical signal to the display 86, wherein the display 86 may present data indicative of the height 42, 46 (e.g., a height in millimeters, centimeters, inches) of the soldering wave 16 at one or more locations. Furthermore, the display 86 may present data, in real-time, indicative of height variability (e.g., a difference of height 42 and height 46 or vice versa) across one or more dimensions of the soldering wave 16. In some embodiments, the control circuitry 82 may also send an electrical signal to the display 86 to present one or more setpoints to the operator. For example, the control circuitry 82 may present, in real-time set points of one or more desired heights of the soldering wave 16, a threshold variability between heights, or both. In this way, the operator for the wave soldering system 10 may view the current wave height (e.g., height 42, height 46, or both) in comparison to set point heights, height variability thresholds, or both.

In another embodiment, the control circuitry 82 may output an electrical signal to one or more alarms 90 based on the wave height (e.g., height 42, 46). For example, upon determination of the height 42, height 46, or both, the control circuitry 82 may send (e.g., issue) a signal or otherwise communicate with the one or more alarms 90 to output one or more alarm actions (e.g., alarm noises, flashing lights). In an embodiment, the control circuitry 82 may output an electrical signal to the one or more alarms 90 based on a comparison of the wave heights (e.g., height 42, 46) to a threshold height. For example, upon determination that height 42, height 46, or both are above or below a threshold height, the control circuitry 82 may send or otherwise communicate an electrical signal to the one or more alarms 90 indicating the threshold height has been breached.

In another embodiment, the control circuitry 82 may output an electrical signal to the one or more alarms 90 based on a comparison of the variability between the wave heights (e.g., height 42, height 46) to a threshold height variability. For example, upon determination that a variability of the wave (e.g., the difference between height 42 and wave height 46 or vice versa) is above a threshold height variability, the control circuitry 82 may send or otherwise communicate an electrical signal to the one or more alarms indicating the threshold height variability has been breached. It should be noted that although two soldering wave height sensors 38 are discussed in the embodiments in determining wave height or wave height variability, any number of soldering wave height sensors 38 may be used.

In a further embodiment, the control circuitry 82 may stop (e.g., suspend) one or more components of the wave soldering system 10 based on the wave height. For example, upon determination of the height 42, height 46, or both, the control circuitry 82 may send an electrical signal or otherwise communicate with the production track 20 (e.g., a production track controller, a production track actuator) to slow, increase, or stop movement of the production track 20. Specifically, the control circuitry 82 may control the production track 20 based on a comparison of the height 42 or the height 46 to a threshold height. For example, upon determination that height 42, height 46, or both are above or below the threshold height, the control circuitry 82 may send or otherwise communicate an electrical signal to the production track controller and/or the production track actuator to stop the movement of the production track 20, preventing the PCBs from translating over an uneven soldering wave 16.

In another embodiment, the control circuitry 82 may output an electrical signal to a production track controller and/or production track actuator based on the height variability to a threshold height variability. For example, upon determination that a height variability (e.g., the difference between height 42 and height 46 or vice versa) is above a threshold height variability, the control circuitry 82 may control the production track 20 to stop operation, via, for example, stopping the flow of power to a component of the production track 20 (e.g., an actuator).

In some embodiments, a threshold wave height and/or a threshold wave height variability for outputting an alarm may be different than a threshold wave height and/or a threshold wave height variability for controlling the production track 20. For example, in an embodiment, the control circuitry 82 may include a first threshold wave height corresponding to a threshold for the one or more alarms 90. The control circuitry 82 may include a second threshold wave height corresponding to a threshold for control of the production track 20. In some embodiments, the first threshold wave height may be less than the second threshold wave height. For instance, as height 42, 46 increases, the height 42, 46 may first pass (e.g., breach) the first threshold wave height, corresponding to a threshold for the one or more alarms 90. The control circuitry 82 may then send or otherwise communicate an electrical signal to the one or more alarms 90 to perform one or more alarm actions (e.g., visually, and/or verbally warning the operator of an increasing height 42, 46).

As the wave height increases past the first threshold wave height, the height 42, 46 may breach the second threshold wave height corresponding to the threshold for control of the production track 20. As discussed above, the control circuitry 82 may then send or otherwise communicate an electrical signal to the production track 20 to shut down or otherwise control the production track 20 to prevent PCBs from continuing over the soldering wave 16. In this way, upon an increase of the height 42, 46 past the second threshold wave height (e.g., production track threshold), the production track 20 may shut down (e.g., stop moving the PCB over the soldering wave 16) before the PCBs are passed over the soldering wave 16, reducing soldering errors due to greater than desired wave heights. As will be appreciated, a similar process may be undergone for breaching a lower boundary wave height threshold.

As discussed above, the wave soldering system 10 may include one or more wave pumps 32 to circulate, adjust, or otherwise control the flow of molten material defining the soldering wave 16. For example, the wave pump 32 may increase or decrease the flow velocity of molten material of the soldering wave 16, which may result in increasing or decreasing the wave height (e.g., height 42, 46) respectively. The wave pump 32 may also regulate molten material flow rate to ensure uniform soldering to the bottom of the PCB.

In some embodiment, the control circuitry 82 may output an electrical signal to or otherwise communicate with the wave pump 32 based on the wave height (e.g., heights 42, 46). For example, upon determination of the height 42, height 46, or both, the control circuitry 82 may send an electrical signal to or otherwise communicate with the wave pump 32 to adjust (e.g., increase, decrease) a flow of molten material defining the soldering wave 16. In an embodiment, the control circuitry 82 may control the wave pump 32 based on a comparison of the wave height to a threshold wave height and/or based on a deviation of the wave height from a set point wave height. For example, upon determination that height 42, height 46, or both are above or below a threshold height, the control circuitry 82 may send or otherwise communicate an electrical signal to the wave pump 32 to adjust the flow of molten material of the soldering wave 16. Specifically, as an example, as the height 42, 46 increases past a threshold wave height (e.g., an upper boundary), the control circuitry 82 may send an electrical signal or may otherwise communicate with the wave pump 32 to decrease flow of molten material to the soldering wave 16, which may decrease the height 42, 46. Likewise, as the height 42, 46 decreases past a threshold wave height (e.g., a lower boundary), the control circuitry 82 may send an electrical signal to or otherwise communicate with the wave pump 32 to increase flow of molten material to the soldering wave 16, which may increase the height 42, 46. In this way, the control circuitry 82 may monitor and adjust the wave height with reduced human intervention, a decrease in system downtime due to processing errors (e.g., process drifts), and increased production efficiency.

In an embodiment, the control circuitry 82 may receive a signal indicating one or more operating parameters of the wave pump 32, where the control circuitry 82 may predict a wave pump 32 condition (e.g., failure, process drift) before the PCB 12 is affected, based on the signal. Specifically, the control circuitry 82 may perform one or more prediction algorithms using the detected wave pump 32 operating parameter (e.g., the signal indicating one or more operating parameters of the wave pump 32), the wave heights 42, 46, and/or another parameter to predict a future wave pump 32 condition (e.g., mechanical failure and/or process drift). Based on the prediction, the control circuitry 82 may send a signal to output an alarm, output a display, automatically adjust one or more parameters of the wave pump 32, actuate the production track 20, and/or another suitable action. In this way, the wave pump 32 may be monitored to decrease system downtime due to processing errors (e.g., process drifts, mechanical failures), and increase production efficiency.

In another embodiment, the control circuitry 82 may output an electrical signal to or otherwise communicate with the wave pump 32 based on the variability between the wave heights (e.g., height 42, height 46, wave heights at different locations of the soldering wave 16). For example, upon determination that height variability (e.g., the difference between height 42 and wave height 46 or vice versa) is above a threshold height variability, the control circuitry 82 may send an electrical signal to or otherwise communicate with the wave pump 32 to adjust flow of the molten material to the soldering wave 16. In this way, the control circuitry 82 may monitor and adjust the soldering wave 16 to decrease height variability, increasing solder uniformity on the PCBs, reducing human intervention, decreasing system downtime, and increasing production efficiency.

As discussed above, the wave soldering system 10 may include one or more actuators 28 to adjust (coarsely adjust) the soldering wave's 16 vertical position. For example, the actuator 28 may be disposed at the bottom of the soldering wave producing machine 14 to move the soldering wave producing machine 14 vertically (e.g., up, down), thereby moving the position of the soldering wave 16 vertically relative to a PCB board. The actuator 28 may be any type of actuator suitable to adjust a height of the soldering wave producing machine 14, such as, a hydraulic actuator (e.g., hydraulic motor), a mechanical actuator (e.g., gear mechanisms), a pneumatic actuator, an electric actuator (e.g., electric motors, solenoids, stepper motors) and/or any other suitable actuator capable of adjusting the height of the soldering wave producing machine 14. Further, as mentioned above, the wave soldering system 10, and more specifically the soldering wave producing machine 14, may include one or more baffles 98 to adjust a configuration of the soldering wave 16. For example, the baffles 98 may be disposed within the soldering wave producing machine to change (e.g., increase, decrease) an angle (e.g., an angle relative to a wall or base of the soldering wave producing machine 14) to alter a flow of the molten material. In this way, the wave shape may be altered to produce a desired configuration capable of soldering desired locations on the PCB board. The one or more baffles 98 may extend along one or more dimensions of the soldering wave producing machine 14 and through the molten material of the soldering wave 16. As such, the one or more baffles 98 may be any material suitable to withstand high heat while maintaining structural integrity to support altering flow of the soldering wave 16.

In some embodiments, the control circuitry 82 may output an electrical signal to or otherwise communicate with the one or more baffles 98 (e.g., an actuator of the baffle 98) based on the wave height, and/or a desired soldering configuration of the PCB. For example, upon determination of the height 42, height 46, or both, the control circuitry 82 may send an electrical signal or otherwise communicate with the one or more baffles 98 to change the angle of the one or more baffles 98 to alter the flow of molten material, creating alternate flow configurations. In an embodiment, the control circuitry 82 may control the one or more baffles 98 based on a comparison of the wave height to a threshold wave height and/or based on a deviation of the wave height from a set point height. For example, upon determination that height 42, height 46, or both are above or below a threshold, the control circuitry 82 may send or otherwise communicate an electrical signal to the one or more baffles 98 to adjust a configuration of flow of the soldering wave 16. Specifically, as an example, as the height 42, 46 increases past a threshold wave height (e.g., an upper boundary), the control circuitry 82 may send an electric signal or may otherwise communicate with the one or more baffles 98 (e.g., an actuator of the one or more baffles) to change the angle of the one or more baffles 98 to decrease a height of the soldering wave 16 at one or more locations. Likewise, as the height 42, 46 decreases past a threshold wave height (e.g., a lower boundary), the control circuitry 82 may send an electric signal or otherwise communicate with the one or more baffles 98 to change the angle of the one or more baffles 98 to increase a height of the soldering wave 16. In this way, the control circuitry 82 may adjust a flow configuration of the soldering wave 16 to ensure proper soldering of the PCB, reducing the amount human intervention and stoppages, increasing soldering uniformity and quality, and increasing PCB production efficiency.

In another embodiment, the control circuitry 82 may output an electrical signal to or otherwise communicate with the one or more baffles based on the variability between the wave heights (e.g., height 42, height 46, wave heights at different locations of the soldering wave 16). For example, upon determination that the variability of the wave height (e.g., the difference between height 42 and height 46 or vice versa) is above a threshold height variability, the control circuitry 82 may send an electrical signal to or otherwise communicate with the one or more baffles 98 to adjust or alter a soldering wave 16 configuration to create a uniform soldering wave 16 and/or create a soldering wave 16 configuration suitable for desired soldering of a PCB. In this way, the control circuitry 82 may control a wave configuration based on a desired soldering of a PCB and/or based on the variability of the wave heights.

As a specific example, embodiments of the PCB may include varying sizes of components requiring soldering. As such, the desired depth of the components within the soldering wave 16 may vary based on the location of the components on the PCB board. Aspects of this disclosure allow for measuring, detecting, and/or adjusting a wave height (e.g., height 42, 46) via one or more soldering wave height sensors 38, at multiple soldering wave 16 locations in order to solder varying sizes of components of the PCB, without the need of multiple PCB passes over the soldering wave 16.

It should be appreciated that although the processes above relating to displaying, alarming, controlling the production track, adjusting the wave height, adjusting the wave producing machine 14 height, and adjusting the baffles 98, are discussed in singularity, any combination of the above-mentioned processes may be done simultaneously. For example, in an embodiment, the wave pump 32 may be controlled to decrease molten material flow (e.g., reducing height 42, 46) while the one or more alarms produce one or more alarm actions. In another embodiment, the production track 20 may be controlled to stop PCB movement while the one or more alarms 90 produce one or more alarm actions.

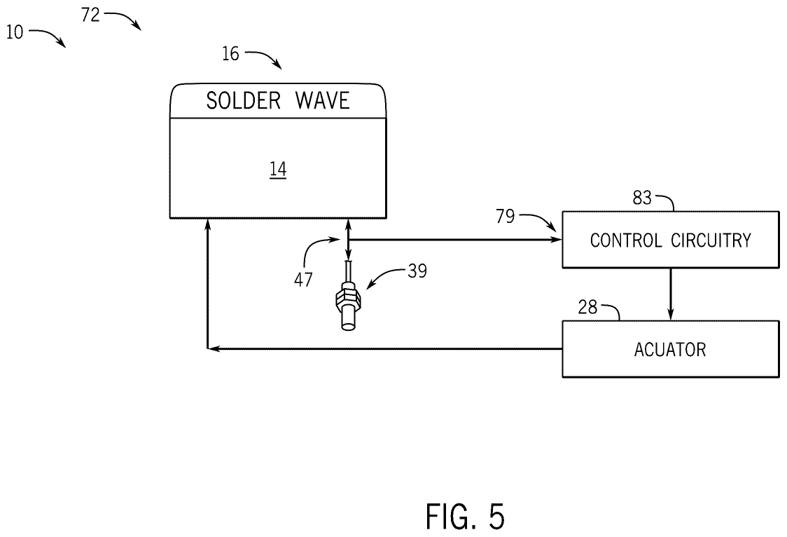

Referring now to FIG. 5, a block diagram of a control system 72 for a wave soldering system 10 is shown. In embodiments, the control system 72 may be a part of control system 70, and the control circuitry 83 is the same as control circuitry 82. In other embodiments, the control system 72 is a separate control system utilizing separate components (e.g., control circuitry 83 is separate from control circuitry 82). In any case, the wave soldering system 10 may include one or more wave producing machine height sensors 39 (e.g., solder pot height sensor) that may detect a position (e.g., height) of the wave producing machine 14. The wave producing machine height sensor 39 may be similar to the wave height sensors 38 discussed above (e.g., eddy current sensor). In any event, the wave producing machine height sensor 39 may be positioned below (e.g., vertically below) the wave producing machine 14, and may detect a relative position of the wave producing machine in a manner similar to as discussed above. The wave producing machine height sensor 39 may detect and send measurements indicating a wave producing machine height (e.g., height 47) to one or more input pins 79 of control circuitry 83. For example, the wave producing machine height sensor 39 may receive data indicative of a wave producing machine height (e.g., changes of electrical properties of the wave producing machine 14 (e.g., Eddy currents) and/or changes in the magnetic field of the sensing coils) and send said data, via an electrical signal, to the control circuitry 83. The control circuitry 83 may then convert the electrical signal, including data indicative of the height 47 to a measure of distance (e.g., a height measured in a distance (e.g., millimeters, centimeters)). In some embodiments, the wave producing machine height sensor 39 may include internal control circuitry to convert the detected data into a converted wave producing machine height, where the converted wave producing machine height may further be relayed to the control circuitry 83 to make one or more determinations and/or perform one or more actions. As will be appreciated, the use of a wave producing machine height sensor 39 incorporating eddy current detecting capabilities may provide distinct advantages over traditional wave producing machine (e.g., solder pot) height sensors, such as, increasing sensing reliability, reducing mechanical failure, and increasing detecting precision, all of which may increase PCB soldering efficiency.

In some embodiments, the control circuitry 83 may output an electrical signal to or otherwise communicate with the actuator 28 based on the height 47. For example, upon determination of the height 47 the control circuitry 83 may send an electric signal or otherwise communicate with the actuator 28 to adjust (e.g., increase, decrease) a height of the wave producing machine 14 (e.g., solder pot). In an embodiment, the control circuitry 83 may control the actuator 28 based on a comparison of the wave producing machine height (e.g., height 47) to a threshold wave producing machine height. For example, upon determination that height 47 is above or below a threshold, the control circuitry 83 may send or otherwise communicate an electrical signal to the actuator 28 to adjust the height of the soldering wave producing machine 14. Specifically, as an example, as the height 47 increases past a threshold wave producing machine height (e.g., an upper boundary), the control circuitry 83 may send an electric signal or may otherwise communicate with the actuator 28 to decrease the height of the soldering wave producing machine 14. Likewise, as the height 47 decreases past a threshold wave height (e.g., a lower boundary), the control circuitry 83 may send an electric signal to or may otherwise communicate with the actuator 28 to increase the height of the wave producing machine 14. In this way, the control circuitry 83 may adjust (e.g., coarsely adjust) the wave producing machine position relative the PCB, reducing the human intervention and stoppages, increasing soldering uniformity and quality, and increasing PCB production efficiency.

In another embodiment, the control circuitry 83 may output an electrical signal to or otherwise communicate with the actuator 28 based on the detected wave heights (discussed in FIG. 4) and the wave producing machine height (e.g., height 47). For example, upon determination of the wave height and the wave producing machine height, the control circuitry 83 may send an electrical signal to or otherwise communicate with the actuator 28 to adjust (e.g., lower, raise) the soldering wave producing machine 14 relative to the wave height sensors or the wave producing machine height sensor 39. In this way, the control circuitry 83 may separate (e.g., completely separate) the soldering wave 16 from the PCB to reduce and/or prevent unequal soldering of the PCB, thus decreasing system downtime due to soldering errors, and increasing production efficiency.

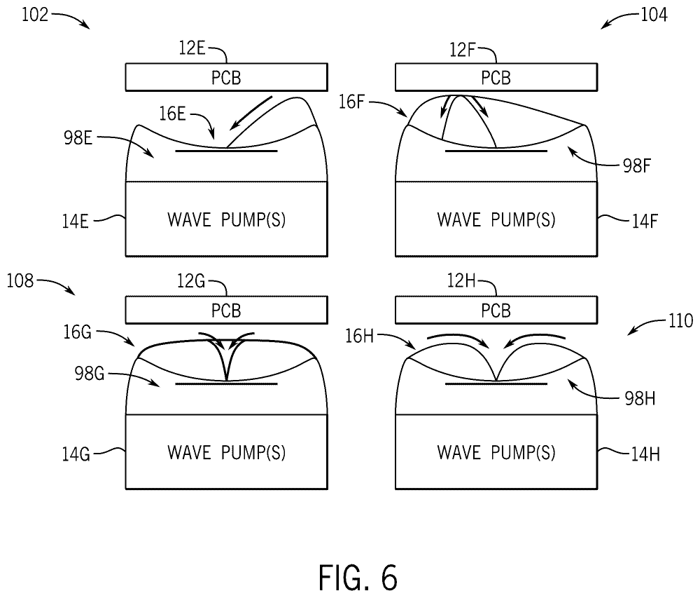

Referring now to FIG. 6, multiple wave configurations 102, 104, 108, 110 are shown. As discussed above, the soldering wave producing machine 14E. 14F, 14G, 14H may include one or more baffles (e.g., 98E, 98F, 98G, 98H) to adjust the soldering wave 16 to produce a desired wave configuration. As will be appreciated, the baffles 98 may be adjusted (e.g., adjusted via a baffle actuator, adjusted manually) to alter a flow of molten material to create different wave configurations (e.g., wave peaks at various PCB locations). For example, wave configuration 102 as illustrated shows a wave configuration with one peak located at one side of the PCB 12E. In other embodiments, such as wave configurations 104, 108, and 110, the soldering wave 16 may include multiple peaks at the same or different locations of the PCB 12F, 12G, 12H. In this way, PCBs 12 including multiple components, at various PCB 12 locations may be soldered in an efficient matter. Further, as discussed above, the actuation of the baffles 98 to produce a desired wave configuration, such as wave configurations 102, 104, 108, and 110, may be controlled through monitoring of the wave heights with one or more soldering wave height sensors. For example, the one or more soldering wave height sensors and control circuitry may monitor and adjust the baffles 98 in a manner as discussed above to achieve a desired wave configuration.

In some embodiments, the one or more soldering wave height sensors may detect one or more additional aspects of the soldering wave. For example, the soldering wave height sensors may detect a flow rate of the soldering wave, a rotational speed of the soldering wave, a rotational direction of the soldering wave, or another aspect of the soldering wave alone or in combination with the detection of the height. Specifically, the soldering wave height sensors may detect signals indicative of a movement of the soldering wave. The soldering wave height sensors may further communicate the additional signals (e.g., signal anomalies) to the control circuitry (e.g., additional to the signals indicative of the soldering wave height), where the control circuitry may further determine a flow characteristic (e.g., flow rate, rotational speed) of the soldering wave based on the signal. In an embodiment, the control circuitry may include (e.g., within the memory) algorithms (e.g., virtual models), that may be performed by the processor. The algorithms, upon initialization by the control circuitry, may output flow characteristics based on one or more signals detected by the soldering wave height sensor. In any case, based on the one or more additional aspects of the soldering wave, cither alone or in combination with the detected soldering wave height, one or more actions may be performed to increase soldering efficiency and reduce errors. For example, based on a detected rotational speed or direction of the soldering wave, the baffles 98 may be adjusted to alter a flow of molten material to create a desired wave configuration. As another example, based on the detected rotational speed or direction of the soldering wave, a wave configuration may be determined.

While specific embodiments and applications of the disclosure have been illustrated and described, it is to be noted that the disclosure is not limited to the precise configurations and devices disclosed herein. Accordingly, many changes may be made to the details of the above-described embodiments without departing from the underlying principles of this disclosure. The scope of the present disclosure should, therefore, be determined only by the following claims.

Indeed, the embodiments set forth in the present disclosure may be susceptible to various modifications and alternative forms, specific embodiments have been shown by way of example in the drawings and have been described in detail herein. However, it may be noted that the disclosure is not intended to be limited to the particular forms disclosed. The disclosure is to cover all modifications, equivalents, and alternatives falling within the spirit and scope of the disclosure as defined by the following appended claims. In addition, the techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). For any claims containing elements designated in any other manner, however, it is intended that such elements are not to be interpreted under 35 U.S.C. 112 (f).

What is claimed is:

1. A soldering system comprising:
a first solder wave height sensor configured to generate a first sensor signal;
a second solder wave height sensor configured to generate a second sensor signal; and
control circuitry configured to control an operation of the soldering system based on the first sensor signal and the second sensor signal.

2. The soldering system of claim 1, wherein the first solder wave height sensor and the second solder wave height sensor comprise an eddy current sensor.

3. The soldering system of claim 1, comprising a wave of the soldering system, wherein the first sensor signal indicates a first height of the wave and the second sensor signal indicates a second height of the wave.

4. The soldering system of claim 3, comprising an electronic display configured to provide real time display of the first height and the second height.

5. The soldering system of claim 3, wherein the control circuitry is configured to determine a variation between the first height and the second height.

6. The soldering system of claim 5, wherein the control circuitry is configured to issue an alarm based on the variation between the first height and the second height.

7. The soldering system of claim 5, comprising a production track, wherein the control circuitry is configured to control the production track based on the variation between the first height and the second height.

8. The soldering system of claim 7, wherein the control circuitry is configured to slow or stop the production track based on the variation exceeding a threshold variation of the first height and the second height.

9. The soldering system of claim 1, comprising:
a solder pot height sensor, configured to generate a third sensor signal; and
an actuator configured to provide a height adjustment to a solder pot to bring a solder wave closer to or further from the first solder wave height sensor, the second solder wave height sensor, or both, based on the first sensor signal, the second sensor signal, the third sensor signal, or a combination thereof.

10. The soldering system of claim 1, comprising a solder wave pump configured to provide a height adjustment to a solder wave to bring the solder wave closer to or further from the first solder wave height sensor, the second solder wave height sensor, or both, based on the first sensor signal or the second sensor signal.

11. The soldering system of claim 1, comprising one or more baffles configured to provide a flow configuration to a solder wave based on the first sensor signal or the second sensor signal.

12. A control system for wave soldering comprising:
a first input pin configured to receive a first sensor signal from a first solder wave height sensor;
a second input pin configured to receive a second sensor signal from a second solder wave height sensor; and
control circuitry configured to control a height of a soldering wave based on the first sensor signal and the second sensor signal.

13. The control system of claim 12, wherein the height is a first height, and the control circuitry is configured to control the first height and a second height of the soldering wave to be a substantially equal height, based on the first sensor signal and the second sensor signal.

14. The control system of claim 12, comprising production track configured to move a printed circuit board over the soldering wave, wherein the control circuitry is configured to suspend movement of the production track based on a variation between the first sensor signal and the second sensor signal.

15. The control system of claim 12, comprising an alarm configured to perform one or more alarm action, wherein the control circuitry is configured to operate the alarm based on a variation between the first sensor signal and the second sensor signal.

16. A sensor configuration comprising:
an eddy current sensor, wherein the eddy current sensor is configured to detect one or more parameters of a soldering wave; and
a thermal resistant layer disposed on the eddy current sensor configured to shield the eddy current sensor from thermal energy dissipating from the soldering wave, wherein the thermal resistant layer comprises a nano-particle coating.

17. The sensor configuration of claim 16, wherein the nano-particle coating comprises nanobead glass or nanobead ceramic.

18. The sensor configuration of claim 16, comprising a thermal regulator disposed on the eddy current sensor, configured to maintain a temperature of the eddy current sensor.

19. The sensor configuration of claim 16, comprising a support structure configured to suspend the eddy current sensor above the soldering wave.

20. The sensor configuration of claim 19, wherein the support structure and the thermal resistant layer are coupled together and define a cavity configured to removably receive the eddy current sensor.
